(19) United States
(12) Patent Application Publication
(10) Pub. No.: US 2026/0149425 A1
(43) Pub. Date: May 28, 2026

(54) TRIMMING AN OFFSET VOLTAGE DRIFT BASED ON MEASUREMENTS AT TWO TEMPERATURES

(71) Applicant: Microchip Technology Incorporated, Chandler, AZ (US)

(72) Inventors: Jim Nolan, Chandler, AZ (US); Milan Rai, Chandler, AZ (US); Kumen Blake, Gilbert, AZ (US)

(73) Assignee: Microchip Technology Incorporated, Chandler, AZ (US)

(21) Appl. No.: 19/049,698

(22) Filed: Feb. 10, 2025

Related U.S. Application Data
(60) Provisional application No. 63/724,435, filed on Nov. 25, 2024.

(51) Int. Cl. H03F 3/45; H03F 3/217

(52) U.S. Cl. CPC H03F 3/45766; H03F 3/2175; H03F 2200/468; H03F 2203/45538

(57) ABSTRACT

A system and method for compensating for offset voltage drift using a static trim based on measurements at two temperatures are disclosed. The method may include reading a first temperature and a second temperature from a temperature sensor, measuring a first untrimmed offset voltage at the first temperature, and measuring a second untrimmed offset voltage at the second temperature. The method may include calculating an offset voltage drift based on a difference between the first and second untrimmed offset voltages and a difference between the first and second temperatures, calculating an offset voltage drift trim using the offset voltage drift, and storing the offset voltage drift trim for application by a first digital-to-analog converter. The method may include calculating an offset voltage trim at the second temperature, using the offset voltage drift trim at the second temperature, and storing the offset voltage trim for application by a second digital-to-analog converter.

### TECHNICAL FIELD

The present disclosure relates to compensating for offset voltage in an electronic device, and, in particular, to compensating for offset voltage drift using a static trim based on measurements at two temperatures.

### BACKGROUND

Amplifier offset voltage drift refers to the gradual change in the output voltage of an amplifier over time, even when the input signal remains constant. This change is typically caused by variations in temperature and power supply voltage. For example, over a 100-degree temperature range (e.g., from 25° C. to 125° C.), the offset voltage may change by +/−1 millivolt (mV) or more. Offset voltage drift can be a problem in many applications, as it can lead to inaccurate measurements, signal distortion, and system instability. For example, in audio amplifiers, offset voltage drift can cause a low-frequency hum or buzz in the output signal. In instrumentation amplifiers, offset voltage drift can lead to errors in measurements, especially over long periods of time.

Offset voltage trim is a technique used to reduce the output voltage of an amplifier when there is no input signal. This offset voltage can arise due to various factors like component mismatches, temperature variations, or power supply fluctuations. By adjusting a specific component or circuit parameter, the offset voltage may be reduced.

Amplifier offset voltage drift may be a significant error in an application and may be difficult to correct at a system level. Additionally, complementary metal-oxide-semiconductor (CMOS) amplifiers may have an offset voltage drift and an initial offset voltage that may not be correlated on a part-to-part basis.

### SUMMARY OF THE INVENTION

Aspects provide systems and methods for compensating for offset voltage drift using a static trim based on measurements at two temperatures. Examples of the present disclosure may include a system. The system may include a first digital-to-analog converter to apply an offset voltage drift trim. The system may also include a second digital-to-analog converter to apply an offset voltage trim. The system may additionally include a temperature sensor. The system may further include a control circuit. The control circuit may be configured to read a first temperature from the temperature sensor. The control circuit may also be configured to measure a first untrimmed offset voltage at the first temperature. The control circuit may be to read a second temperature from the temperature sensor and measure a second untrimmed offset voltage at the second temperature. The control circuit may be configured to calculate an offset voltage drift based on a difference between the first untrimmed offset voltage and the second untrimmed offset voltage and a difference between the first temperature and the second temperature. The control circuit may additionally be to calculate the offset voltage drift trim using the calculated offset voltage drift and store the offset voltage drift trim. The control circuit may further be to calculate the offset voltage trim at the second temperature using the offset voltage drift trim at the second temperature and store the offset voltage trim.

In combination with any of the above examples, the first digital-to-analog converter, the second digital-to-analog converter, and the temperature sensor may be contained in a semiconductor package.

In combination with any of the above examples, the control circuit may be configured to store an average differential non-linearity (DNL) of the first digital-to-analog converter. The control circuit may also be configured to store an average DNL of the second digital-to-analog converter.

In combination with any of the above examples, the offset voltage drift trim and the offset voltage trim may be stored in one-time programmable memory.

In combination with any of the above examples, the control circuit may be configured to store an identifier of an integrated circuit that includes the first digital-to-analog converter and the second digital-to-analog converter.

In combination with any of the above examples, the control circuit may be configured to calculate the offset voltage drift trim and calculate the offset voltage drift trim for a p-channel metal-oxide semiconductor (PMOS) region of an amplifier and for a n-channel metal-oxide semiconductor (NMOS) region of the amplifier.

In combination with any of the above examples, the temperature sensor may be contained on an integrated circuit with the first digital-to-analog converter and the second digital-to-analog converter.

Alone or in combination with any of the above examples, examples of the present disclosure may include a method. The method may include reading a first temperature from a temperature sensor and measuring a first untrimmed offset voltage at the first temperature. The method may also include reading a second temperature from the temperature sensor and measuring a second untrimmed offset voltage at the second temperature. The method may include calculating an offset voltage drift based on a difference between the first untrimmed offset voltage and the second untrimmed offset voltage and a difference between the first temperature and the second temperature. The method may additionally include calculating an offset voltage drift trim using the calculated offset voltage drift and storing the offset voltage drift trim for application by a first digital-to-analog converter. The method may further include calculating an offset voltage trim at the second temperature using the offset voltage drift trim at the second temperature and storing the offset voltage trim for application by a second digital-to-analog converter.

In combination with any of the above examples, measuring the first untrimmed offset voltage and measuring the second untrimmed offset voltage may be performed while the first digital-to-analog converter, the second digital-to-analog converter, and the temperature sensor are contained in a semiconductor package.

In combination with any of the above examples, the method may include storing an average differential non-linearity (DNL) of the first digital-to-analog converter. The method may also include storing an average DNL of the second digital-to-analog converter.

In combination with any of the above examples, the offset voltage drift trim and the offset voltage trim may be stored in one-time programmable memory.

In combination with any of the above examples, the method may include storing an identifier of an integrated circuit that includes the first digital-to-analog converter and the second digital-to-analog converter.

In combination with any of the above examples, the method may include calculating the offset voltage drift trim for a p-channel metal-oxide semiconductor (PMOS) region of an amplifier and for a n-channel metal-oxide semiconductor (NMOS) region of the amplifier. The method may also include calculating the offset voltage trim for the PMOS region of the amplifier and for the NMOS region of the amplifier.

In combination with any of the above examples, measuring the first temperature and measuring the second temperature may be performed by a temperature sensor contained on an integrated circuit with the first digital-to-analog converter and the second digital-to-analog converter.

Alone or in combination with any of the above examples, examples of the present disclosure may include an apparatus with a control circuit. The control circuit may be configured to read a first temperature from a temperature sensor. The control circuit may also be configured to measure a first untrimmed offset voltage at the first temperature. The control circuit may be configured to read a second temperature from the temperature sensor. The control circuit may additionally be configured to measure a second untrimmed offset voltage at the second temperature. The control circuit may be configured to calculate an offset voltage drift based on a difference between the first untrimmed offset voltage and the second untrimmed offset voltage and a difference between the first temperature and the second temperature. The control circuit may also be configured to calculate an offset voltage drift trim for a first digital-to-analog converter using the calculated offset voltage drift and store the offset voltage drift trim. The control circuit may further be configured to calculate an offset voltage trim for a second digital-to-analog converter at the second temperature using the offset voltage drift trim at the second temperature and store the offset voltage trim.

In combination with any of the above examples, the first digital-to-analog converter, the second digital-to-analog converter, and the temperature sensor may be contained in a semiconductor package.

In combination with any of the above examples, the control circuit may be configured to store an average differential non-linearity (DNL) of the first digital-to-analog converter. The control circuit may also be configured to store an average DNL of the second digital-to-analog converter.

In combination with any of the above examples, the offset voltage drift trim and the offset voltage trim may be stored in one-time programmable memory.

In combination with any of the above examples, the control circuit may be configured to store an identifier of an integrated circuit that includes the first digital-to-analog converter and the second digital-to-analog converter.

In combination with any of the above examples, the control circuit may be configured to calculate the offset voltage drift trim and calculate the offset voltage drift trim for a p-channel metal-oxide semiconductor (PMOS) region of an amplifier and for a n-channel metal-oxide semiconductor (NMOS) region of the amplifier.

### BRIEF DESCRIPTION OF THE DRAWINGS

The figures illustrate examples of systems and methods for compensating for offset voltage drift using a static trim based on measurements at two temperatures.

FIG. 1 is an illustration of an operational amplifier including compensation for offset voltage drift using a static trim based on measurements at two temperatures, according to examples of the present disclosure;

FIG. 2 illustrates the offset voltage of an operational amplifier with and without compensation for offset voltage drift using a static trim based on measurements at two temperatures, according to examples of the present disclosure;

FIG. 3 illustrates a block diagram of an operational amplifier including compensation for offset voltage drift using a static trim based on measurements at two temperatures, according to examples of the present disclosure;

FIG. 4 illustrates a method performed for compensating for offset voltage drift using a static trim using measurements at two temperatures, according to examples of the present disclosure; and

FIG. 5 illustrates a more detailed method performed for compensating for offset voltage drift using a static trim using measurements at two temperatures, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, systems and methods for compensating for offset voltage drift using a static trim based on measurements at two temperatures are provided. Many trimmed amplifiers trim the initial offset voltage but not the offset voltage drift. This technique may worsen the offset voltage drift. These effects may be mitigated by using dynamic offset cancellation, which has drawbacks including, for example, introduction of clock noise into the output and increased amplifier input bias currents. These drawbacks may be unacceptable for some applications. Therefore, an improved method and circuitry for amplifier offset voltage drift trimming is disclosed. The disclosed method and circuitry implement a two-temperature trimming solution to improve drift over a wide temperature range, resulting in an amplifier with improved accuracy and improved ease of manufacture when compared to other approaches for trimming amplifier offset voltage drift. The disclosed method and circuitry use a serial test mode and internal one-time programmable (OTP) memory to store device information at one temperature to be used at a second temperature to apply offset voltage and offset voltage drift trim values. The ability to compensate for the impact of the offset voltage trim on the offset voltage drift may improve accuracy of the amplifier.

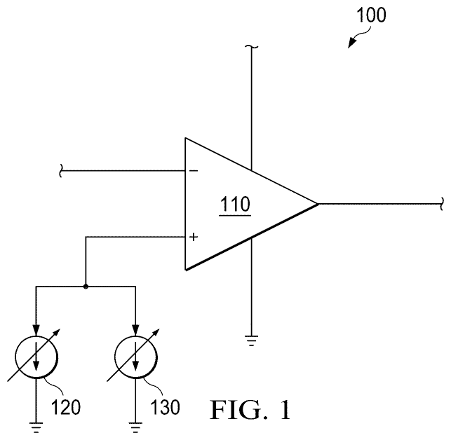

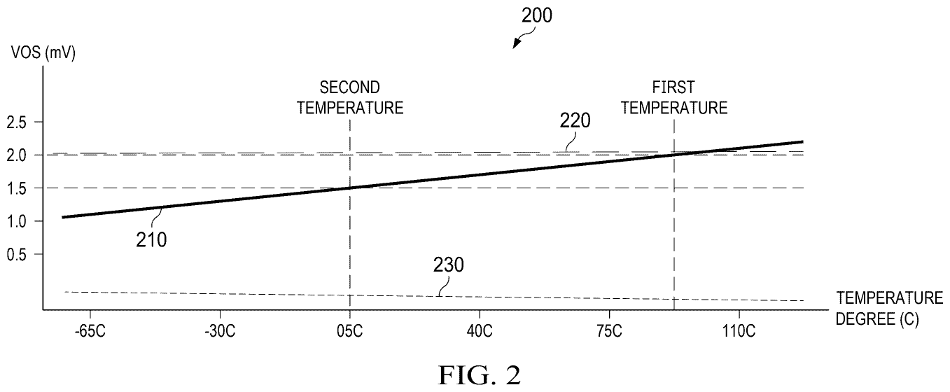

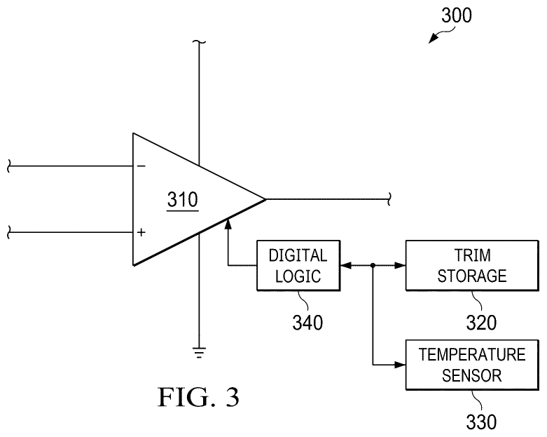

FIG. 1 is an illustration of an operational amplifier including compensation for offset voltage drift using a static trim based on measurements at two temperatures, according to examples of the present disclosure. Operational amplifier 100 may include amplifier 110, digital-to-analog converter (DAC) 120 used for an initial offset voltage (VOS), and DAC 130 used for an offset voltage drift (VOS TC). As explained in more detail with respect to FIGS. 2 and 3, DAC 120 and DAC 130 may be used to implement a two-temperature method for compensating for offset voltage and drift over a wide temperature range in amplifier 110. For example, the two-temperature method may be performed at 5° C. and 105° C. DAC 120 and DAC 130 may be connected to the summing junction of amplifier 110.

DAC 120 and DAC 130 may be used to adjust the offset voltage of amplifier 110. The precision of the trimming provided by DAC 120 and DAC 130 may be based on the resolution of DAC 120 and DAC 130, respectively. A trim code that represents the offset voltage trim may be loaded to DAC 120 and a trim code that represents the offset voltage drift trim may be loaded to DAC 130 during power-up of the operational amplifier. The trim codes may be stored in one-time programmable (OTP) memory.

FIG. 2 illustrates the offset voltage of an operational amplifier with and without compensation for offset voltage drift using a static trim based on measurements at two temperatures, according to examples of the present disclosure. Graph 200 illustrates the untrimmed offset voltage of the operational amplifier (e.g., operational amplifier 100 shown in FIG. 1) as line 210. Line 220 illustrates the trimmed offset voltage of the operational amplifier. Line 230 illustrates the trimmed offset voltage of the operational amplifier after the offset voltage drift trim is applied, resulting in an offset voltage of near 0 millivolts (my).

The offset voltage trim may be determined by measuring the offset voltage at two temperatures. For example, the offset voltage may be measured at a first temperature (e.g., 105° C.). The offset voltage at the first temperature may be stored in memory, such as one-time programmable (OTP) memory. By using internal data OTP memory, the resolution of the data stored may be improved. The offset voltage may also be measured at a second temperature (e.g., 5° C.). In the example shown in FIG. 2, as illustrated by line 210, the offset voltage at the first temperature is approximately 2 mV and the offset voltage at the second temperature is approximately 1.5 mV. The offset voltage drift may be calculated based on the untrimmed offset voltage measurements at the first and second temperature. For example, the offset voltage drift may be calculated using the following formula:

$$\frac{{VOS}_{T 1} - {VOS}_{T 2}}{T 1 - T 2}$$

where VOS_{T1} is the offset voltage at the first temperature, VOS_{T2} is the offset voltage at the second temperature, T1 is the first temperature, and T2 is the second temperature. In the example shown in FIG. 2, line 220 illustrate the offset voltage after accounting of offset voltage drift.

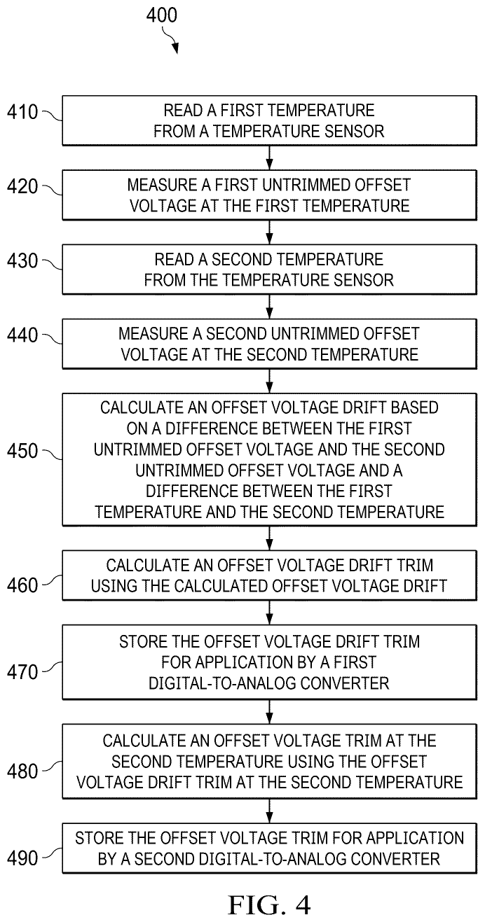

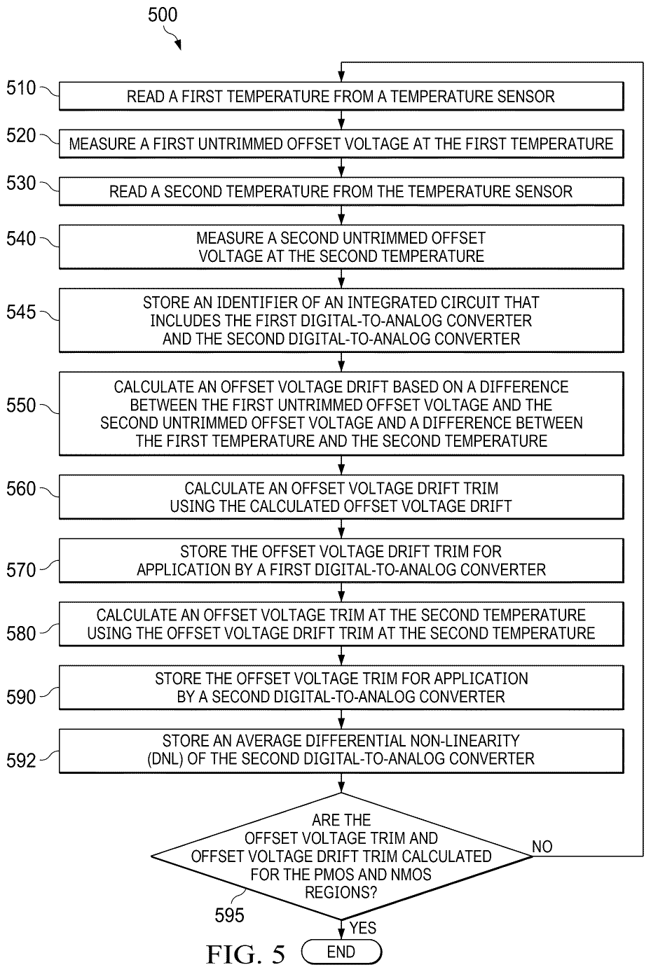

The method for determining the offset voltage trim and the offset voltage drift is described in more detail with respect to FIGS. 4 and 5.

The measurements of the offset voltage at the first and second temperatures may be performed during final testing of the operational amplifier. The measurements may be made using test modes and fuses after the operational amplifier is enclosed in a semiconductor package such that any additional offset voltage due to packaging stress is accounted for in the measurements. By measuring the offset voltage and calculating the offset voltage trim and offset voltage drift during final test, production testing may be simplified and the accuracy of the operational amplifier may be improved. For example, after trimming using the methods of the present disclosure, the operational amplifier may have a maximum offset voltage drift of less than 0.8 microvolts (μV) per degree Celsius from −40° C. to 125° C. and less than 0.5 μV per degree Celsius over a more limited temperature range. A differential non-linearity (DNL) of the DACs may be calculated at the first temperature and stored in OTP. The DNL may also be calculated at the second temperature. The average DNL may be used to correct for the impact of the offset voltage trim on the drift of the operational amplifier. For example, the DAC average step size for each temperature may be calculated. Because the final trim calculations are performed at the second temperature, the DAC average step size may be used to compensate for the potential that the final offset voltage trim may affect the offset voltage drift. The compensation may improve the trim accuracy and save cost during production by avoiding a third test insertion.

FIG. 3 illustrates a block diagram of an operational amplifier including compensation for offset voltage drift using a static trim based on measurements at two temperatures, according to examples of the present disclosure. System 300 may include amplifier 310, trim storage 320, temperature sensor 330, and digital logic 340. Amplifier 310 may be similar to amplifier 110 shown in FIG. 1.

Trim storage 320 may be used to store the trim codes for the offset voltage trim and the offset voltage drift trim. Trim storage 320 may be any suitable type of non-volatile memory (NVM) such as, but not limited to, one time programmable (OTP) memory, programmable read only memory (PROM), electrically erasable PROM (EEPROM), electronic fuse (eFuse), or any combination thereof.

Temperature sensor 330 may be used to measure the temperature of the environment surrounding system 300. In particular, temperature sensor 330 may be used to measure the first temperature and the second temperature used to calculate the offset voltage and offset voltage drift trim codes. Temperature sensor 330 may be included on the chip of amplifier 310 to simplify testing and improve the accuracy of the calculation of the offset voltage and offset voltage drift trim codes. For example, the temperature of the testing environment may not remain constant from test to test and temperature sensor 330 may provide a more accurate temperature reading at the time of testing.

Temperature sensor 330 may be any suitable sensor for measuring the temperature of amplifier 310. For example, temperature sensor 330 may include two precision ratioed current sources and a PNP transistor to generate different voltages between the base and emitter (V_{BE}) voltages on an output pin of the transistor.

Digital logic 340 may read the trim codes for the offset voltage trim and the offset voltage drift trim from trim storage 320 and convert the trim codes into analog signals. Digital logic 340 may output analog signals to amplifier 310 to compensate for offset voltage and offset voltage drift during use of amplifier 310.

FIG. 4 illustrates a method performed for compensating for offset voltage drift using a static trim using measurements at two temperatures, according to examples of the present disclosure. Method 400 may be implemented using an operational amplifier, in combination with a control circuit or processor (e.g., production test equipment or microcontroller), or any other system operable to implement method 400. The control circuit may be implemented by instructions for execution by a processor, analog circuitry, digital circuitry, control logic, digital logic circuits programmed through hardware description language, application specific integrated circuits (ASIC), field programmable gate arrays (FPGA), programmable logic devices (PLD), or any suitable combination thereof, whether in a unitary device or spread over several devices. The control circuit may be implemented by instructions for execution by a processor through, for example, a function, application programming interface (API) call, script, program, compiled code, interpreted code, binary, executable, executable file, firmware, object file, container, assembly code, or object. For example, the control circuit may be implemented by instructions stored in a non-transitory medium such as a memory that, when loaded and executed by a processor such as a central processing unit (CPU) (or any other suitable process), cause the functionality of the control circuit described herein. In some examples, the control circuit may be production test equipment. Although examples have been described above, other variations and examples may be made from this disclosure without departing from the spirit and scope of these disclosed examples.

Method 400 may begin at block 410 where a first temperature may be read from a temperature sensor (e.g., temperature sensor 330 shown in FIG. 3). The first temperature may be stored in memory, such as OTP NVM. The first temperature may be the temperature at which the operational amplifier is exposed. For example, the first temperature may be approximately 105° C. The operational amplifier may be packaged such that the steps of method 400 are performed in package, eliminating package stress effects. The first temperature may be selected to be as close as possible to the highest temperature within the operational temperature range of the operational amplifier.

At block 420, a first untrimmed offset voltage at the first temperature may be measured. The first untrimmed offset voltage at the first temperature may be stored in memory, such as OTP NVM, after measurement.

At block 430, a second temperature may be read from a temperature sensor (e.g., temperature sensor 330 shown in FIG. 3). The second temperature may be stored in memory, such as OTP NVM. The second temperature may be the temperature at which the operational amplifier is exposed. For example, the second temperature may be approximately 5° C. The second temperature may be selected to be as cold as possible, within the operational temperature range of the operational amplifier, that does not cause moisture tracks during the testing process. The second temperature may be selected to provide a wide range between the first and second temperature. A wider range between the first and second temperature may improve trim accuracy. For example, the difference between the first and second temperature may be at least 100° C.

At block 440, a second untrimmed offset voltage at the second temperature may be measured. The second untrimmed offset voltage at the second temperature may be stored in memory, such as OTP NVM, after measurement.

At block 450, an offset voltage drift may be calculated based on a difference between the first untrimmed offset voltage and the second untrimmed offset voltage and a difference between the first temperature and the second temperature. The difference between the first temperature and the second temperature (ATEMP) may be calculated and may be stored in memory, such as OTP NVM. The offset voltage drift may be stored in memory, such as OTP NVM.

At block 460, an offset voltage drift trim may be calculated using the offset voltage drift calculated at block 450. For example, the offset voltage drift may be trimmed using the DAC (e.g., the DAC used for offset voltage drift) closest to approximately 0 μV per degree Celsius. The DAC trim code number of steps (S_{P}) may be calculated according to the following formula:

$${S}_{P} = \frac{( {V}_{OSL} - {S}_{C} * {V}_{STCL} )}{{V}_{STPL}}$$

where V_{OSL} is untrimmed offset voltage measurement at the second temperature, Sc is the offset voltage offset voltage trim code number of steps, V_{STCL} is the offset voltage trim DAC average step size at the second temperature, and V_{STPL} is offset voltage drift trim DAC average step size at the second temperature. The value of S_{P} may be rounded to the nearest trim code.

At block 470, the offset voltage drift trim (calculated at block 460) may be stored for application by a first digital-to-analog converter (DAC). The offset voltage drift trim may be programmed using the production test equipment by multiplexing digital signals on the operational amplifier IN+, IN−, and OUT pins.

At block 480, an offset voltage trim at the second temperature may be calculated using the offset voltage drift trim at the second temperature. For example, the offset voltage may be trimmed using the DAC used for offset voltage trim closest to approximately 0. The DAC trim code number of steps (Sc) may be calculated according to the following formula:

$${S}_{C} = \frac{( {V}_{OSTC} * {V}_{STPL} - {M}_{SP} * {V}_{OSL} )}{( {M}_{SC} * {V}_{STPL} - {M}_{SP} * {V}_{STCL} )}$$

where V_{OSTC} is untrimmed offset voltage drift (ΔVOS/ΔTEMP), V_{STPL} is offset voltage drift trim DAC average step size at the second temperature, V_{OSL} is untrimmed offset voltage measurement at the second temperature, V_{STCL} is the offset voltage trim DAC average step size at the second temperature, M_{SP} is the offset voltage drift trim DAC TC (ΔVOS/(# of steps*ΔTEMP)), and M_{SC} is the offset voltage trim DAC TC (ΔVOS/(# of steps*ΔTEMP)). The value of Sc may be rounded to the nearest trim code.

At block 490, the offset voltage trim (calculated at block 480) may be stored for application by a second digital-to-analog converter (DAC). The offset voltage trim may be programmed using the production test equipment by multiplexing digital signals on the operational amplifier IN+, IN−, and OUT pins.

While method 400 is described as the first temperature being greater than the second temperature, method 400 may be performed where the first temperature is less than the second temperature.

Although FIG. 4 discloses a particular number of operations related to method 400, method 400 may be executed with greater or fewer operations than those depicted in FIG. 4. In addition, although FIG. 4 discloses a certain order of operations to be taken with respect to method 400, the operations comprising method 400 may be completed in any suitable order.

FIG. 5 illustrates a more detailed method performed for compensating for offset voltage drift using a static trim using measurements at two temperatures, according to examples of the present disclosure. Method 500 may be implemented using an operational amplifier, in combination with a control circuit or processor (e.g., production test equipment or microcontroller), or any other system operable to implement method 500. The control circuit may be implemented by instructions for execution by a processor, analog circuitry, digital circuitry, control logic, digital logic circuits programmed through hardware description language, application specific integrated circuits (ASIC), field programmable gate arrays (FPGA), programmable logic devices (PLD), or any suitable combination thereof, whether in a unitary device or spread over several devices. The control circuit may be implemented by instructions for execution by a processor through, for example, a function, application programming interface (API) call, script, program, compiled code, interpreted code, binary, executable, executable file, firmware, object file, container, assembly code, or object. For example, the control circuit may be implemented by instructions stored in a non-transitory medium such as a memory that, when loaded and executed by a processor such as a central processing unit (CPU) (or any other suitable process), cause the functionality of the control circuit described herein. In some examples, the control circuit may be production test equipment. Although examples have been described above, other variations and examples may be made from this disclosure without departing from the spirit and scope of these disclosed examples.

Method 500 may begin at block 510 where a first temperature may be read from a temperature sensor (e.g., temperature sensor 330 shown in FIG. 3). The first temperature may be stored in memory, such as OTP NVM. The first temperature may be the temperature at which the operational amplifier is exposed. For example, the first temperature may be approximately 105° C. The operational amplifier may be packaged such that the steps of method 500 are performed in package, eliminating package stress effects. The first temperature may be selected to be as close as possible to the highest temperature within the operational temperature range of the operational amplifier.

At block 520, a first untrimmed offset voltage at the first temperature may be measured. The first untrimmed offset voltage at the first temperature may be stored in memory, such as OTP NVM, after measurement.

At block 530, a second temperature may be read from a temperature sensor (e.g., temperature sensor 330 shown in FIG. 3). The second temperature may be stored in memory, such as OTP NVM. The second temperature may be the temperature at which the operational amplifier is exposed. For example, the second temperature may be approximately 5° C. The second temperature may be selected to be as cold as possible, within the operational temperature range of the operational amplifier, that does not cause moisture tracks during the testing process. The second temperature may be selected to provide a large range between the first and second temperature. A wider range between the first and second temperature may improve trim accuracy. For example, the difference between the first and second temperature may be at least 100° C.

At block 540, a second untrimmed offset voltage at the second temperature may be measured. The second untrimmed offset voltage at the second temperature may be stored in memory, such as OTP NVM, after measurement.

At block 545, an identifier of the integrated circuit that includes the first digital-to-analog converter and the second digital-to-analog converter that are used for the offset voltage trim and offset voltage drift trim such as, but not limited to, the serial ID of the operational amplifier may be stored in memory, such as OTP NVM. By storing the serial ID of the operational amplifier in memory on the chip forming the operational amplifier, opportunities of device mix-up between tests may be reduced.

At block 550, an offset voltage drift may be calculated based on a difference between the first untrimmed offset voltage and the second untrimmed offset voltage and a difference between the first temperature and the second temperature. The difference between the first temperature and the second temperature (ΔTEMP) may be calculated and may be stored in memory, such as OTP NVM. The offset voltage drift may be stored in memory, such as OTP NVM.

At block 560, an offset voltage drift trim may be calculated using the offset voltage drift calculated at block 550. For example, the offset voltage drift may be trimmed using the DAC (e.g., the DAC used for offset voltage drift) closest to approximately 0 μV per degree Celsius. The DAC trim code number of steps (S_{PP}) may be calculated according to the following formula:

$${S}_{P} = \frac{( {V}_{OSL} - {S}_{C} * {V}_{STCL} )}{{V}_{STPL}}$$

where V_{OSL} is untrimmed offset voltage measurement at the second temperature, Sc is the offset voltage offset voltage trim code number of steps, V_{STCL} is the offset voltage trim DAC average step size at the second temperature, and V_{STPL} is offset voltage drift trim DAC average step size at the second temperature. The value of S_{P} may be rounded to the nearest trim code.

At block 570, the offset voltage drift trim (calculated at block 560) may be stored for application by a first digital-to-analog converter (DAC). The offset voltage drift trim may be programmed using the production test equipment by multiplexing digital signals on the operational amplifier IN+, IN−, and OUT pins.

At block 580, an offset voltage trim at the second temperature may be calculated using the offset voltage drift trim at the second temperature. For example, the offset voltage may be trimmed using the DAC used for offset voltage trim closest to approximately 0. The DAC trim code number of steps (Sc) may be calculated according to the following formula:

$${S}_{C} = \frac{( {V}_{OSTC} * {V}_{STPL} - {M}_{SP} * {V}_{OSL} )}{( {M}_{SC} * {V}_{STPL} - {M}_{SP} * {V}_{STCL} )}$$

where V_{OSTC} is untrimmed offset voltage drift (ΔVOS/ΔTEMP), V_{STPL} is offset voltage drift trim DAC average step size at the second temperature, V_{OSL} is untrimmed offset voltage measurement at the second temperature, V_{STCL} is the offset voltage trim DAC average step size at the second temperature, M_{SP} is the offset voltage drift trim DAC TC (ΔVOS/(# of steps*ΔTEMP)), and M_{SC} is the offset voltage trim DAC TC (ΔVOS/(# of steps*ΔTEMP)). The value of Sc may be rounded to the nearest trim code.

At block 590, the offset voltage trim (calculated at block 580) may be stored for application by a second digital-to-analog converter (DAC). The offset voltage trim may be programmed using the production test equipment by multiplexing digital signals on the operational amplifier IN+, IN−, and OUT pins.

At block 592, an average differential non-linearity (DNL) of the second digital-to-analog converter may be stored. The average DNL may be used to correct for the impact of the offset voltage trim on the drift of the operational amplifier. For example, the DAC average step size for each temperature may be calculated. Because the final trim calculations are performed at the second temperature, the DAC average step size may be used to compensate for the potential that the final offset voltage trim may affect the offset voltage drift. The compensation may improve the trim accuracy and save cost during production by avoiding a third test insertion.

At block 595, method 500 may determine whether the offset voltage and offset voltage drift trim is calculated for the n-channel metal-oxide semiconductor (NMOS) and p-channel metal-oxide semiconductor (PMOS) regions of the operational amplifier. If not, method 500 may return to block 510 to calculate the offset voltage and offset voltage drift trim for the other region. Some operational amplifiers may not include both NMOS and PMOS differential pair trim. In these examples, both NMOS and PMOS trim may not be calculated and stored.

While method 500 is described as the first temperature being greater than the second temperature, method 500 may be performed where the first temperature is less than the second temperature.

Although FIG. 5 discloses a particular number of operations related to method 500, method 500 may be executed with greater or fewer operations than those depicted in FIG. 5. In addition, although FIG. 5 discloses a certain order of operations to be taken with respect to method 500, the operations comprising method 500 may be completed in any suitable order.

Although examples have been described above, other variations and examples may be made from this disclosure without departing from the spirit and scope of these disclosed examples.

1. A system, comprising:
a first digital-to-analog converter to apply an offset voltage drift trim;
a second digital-to-analog converter to apply an offset voltage trim;
a temperature sensor; and
a control circuit to:
read a first temperature from the temperature sensor;
measure a first untrimmed offset voltage at the first temperature;
read a second temperature from the temperature sensor;
measure a second untrimmed offset voltage at the second temperature;
calculate an offset voltage drift based on a difference between the first untrimmed offset voltage and the second untrimmed offset voltage and a difference between the first temperature and the second temperature;
calculate the offset voltage drift trim using the calculated offset voltage drift;
store the offset voltage drift trim;
calculate the offset voltage trim at the second temperature using the offset voltage drift trim at the second temperature; and
store the offset voltage trim.

2. The system of claim 1, wherein the first digital-to-analog converter, the second digital-to-analog converter, and the temperature sensor are contained in a semiconductor package.

3. The system of claim 1, wherein the control circuit is to:
store an average differential non-linearity (DNL) of the first digital-to-analog converter; and
store an average DNL of the second digital-to-analog converter.

4. The system of claim 1, wherein the offset voltage drift trim and the offset voltage trim are stored in one-time programmable memory.

5. The system of claim 1, wherein the control circuit is to store an identifier of an integrated circuit that includes the first digital-to-analog converter and the second digital-to-analog converter.

6. The system of claim 1, wherein the control circuit is to calculate the offset voltage drift trim and calculate the offset voltage drift trim for a p-channel metal-oxide semiconductor (PMOS) region of an amplifier and for a n-channel metal-oxide semiconductor (NMOS) region of the amplifier.

7. The system of claim 1, wherein the temperature sensor is contained on an integrated circuit with the first digital-to-analog converter and the second digital-to-analog converter.

8. A method, comprising:
reading a first temperature from a temperature sensor;
measuring a first untrimmed offset voltage at the first temperature;
reading a second temperature from the temperature sensor;
measuring a second untrimmed offset voltage at the second temperature;
calculating an offset voltage drift based on a difference between the first untrimmed offset voltage and the second untrimmed offset voltage and a difference between the first temperature and the second temperature;
calculating an offset voltage drift trim using the calculated offset voltage drift;
storing the offset voltage drift trim for application by a first digital-to-analog converter;
calculating an offset voltage trim at the second temperature using the offset voltage drift trim at the second temperature; and
storing the offset voltage trim for application by a second digital-to-analog converter.

9. The method of claim 8, wherein measuring the first untrimmed offset voltage and measuring the second untrimmed offset voltage is performed while the first digital-to-analog converter, the second digital-to-analog converter, and the temperature sensor are contained in a semiconductor package.

10. The method of claim 8, comprising:
storing an average differential non-linearity (DNL) of the first digital-to-analog converter; and
storing an average DNL of the second digital-to-analog converter.

11. The method of claim 8, wherein the offset voltage drift trim and the offset voltage trim are stored in one-time programmable memory.

12. The method of claim 8, comprising storing an identifier of an integrated circuit that includes the first digital-to-analog converter and the second digital-to-analog converter.

13. The method of claim 8, comprising:
calculating the offset voltage drift trim for a p-channel metal-oxide semiconductor (PMOS) region of an amplifier and for a n-channel metal-oxide semiconductor (NMOS) region of the amplifier; and
calculating the offset voltage trim for the PMOS region of the amplifier and for the NMOS region of the amplifier.

14. The method of claim 8, wherein measuring the first temperature and measuring the second temperature is performed by the temperature sensor contained on an integrated circuit with the first digital-to-analog converter and the second digital-to-analog converter.

15. An apparatus, comprising:
a control circuit to:
read a first temperature from a temperature sensor;
measure a first untrimmed offset voltage at the first temperature;
read a second temperature from the temperature sensor;
measure a second untrimmed offset voltage at the second temperature;
calculate an offset voltage drift based on a difference between the first untrimmed offset voltage and the second untrimmed offset voltage and a difference between the first temperature and the second temperature;
calculate an offset voltage drift trim for a first digital-to-analog converter using the calculated offset voltage drift;
store the offset voltage drift trim;
calculate an offset voltage trim for a second digital-to-analog converter at the second temperature using the offset voltage drift trim at the second temperature; and
store the offset voltage trim.

16. The apparatus of claim 15, wherein the first digital-to-analog converter, the second digital-to-analog converter, and the temperature sensor are contained in a semiconductor package.

17. The apparatus of claim 15, wherein the control circuit is to:
store an average differential non-linearity (DNL) of the first digital-to-analog converter; and
store an average DNL of the second digital-to-analog converter.

18. The apparatus of claim 15, wherein the offset voltage drift trim and the offset voltage trim are stored in one-time programmable memory.

19. The apparatus of claim 15, wherein the control circuit is to store an identifier of an integrated circuit that includes the first digital-to-analog converter and the second digital-to-analog converter.

20. The apparatus of claim 15, wherein the control circuit is to calculate the offset voltage drift trim and calculate the offset voltage drift trim for a p-channel metal-oxide semiconductor (PMOS) region of an amplifier and for a n-channel metal-oxide semiconductor (NMOS) region of the amplifier.
